(19) United States
(12) Patent Application Publication
(10) Pub. No.: US 2019/0106790 A1
(43) Pub. Date: Apr. 11, 2019

(54) METHOD FOR MANUFACTURING A PART OR A SUPPORTED MICROSTRUCTURE BY LASER EXPOSURE OF A METAL OXALATE LAYER

(71) Applicants: CENTRE NATIONAL DE LA RECHERCHE SCIENTIFIQUE, PARIS (FR); UNIVERSITE TOULOUSE III - PAUL SABATIER, Toulouse (FR)

(72) Inventors: Valérie BACO, LABARTHE SUR LEZE (FR); Philippe TAILHADES, SAINT-ORENS (FR); Hoa LE TRONG, RAMONVILLE SAINT AGNE (FR); Isabelle PASQUET, TOULOUSE (FR); Pierre-François CALMON, ODARS (FR); Henri CAMON, REBIGUE (FR); Véronique CONEDERA, TOULOUSE (FR)

(21) Appl. No.: 16/062,436

(22) PCT Filed: Dec. 14, 2016
(86) PCT No.: PCT/FR2016/053433

§ 371 Date: Dec. 13, 2018

(30) Foreign Application Priority Data
Dec. 17, 2015 (FR) 1562694

(51) Int. Cl. C23C 18/08; C23C 18/16; C23C 18/14; C23C 18/20; G03F 7/004

(52) U.S. Cl. CPC C23C 18/08; C23C 18/1612; G03F 7/0047; C23C 18/204; C23C 18/14

(57) ABSTRACT

The invention relates to a process for the manufacture of a metal, ceramic or composite part or of a supported metal, ceramic or composite microstructure by laser irradiation starting from metal oxalates, and also to the part and the microstructure obtained by said process, and to their uses.

The invention relates to a process for the manufacture of a metal, ceramic or composite part or of a supported metal, ceramic or composite microstructure by laser irradiation starting from metal oxalates, and also to the part and the microstructure obtained by said process, and to their uses.

Layers of transparent conductive metals and/or metal oxides, such as ITO (indium tin oxide), have found a wide field of applications as transparent conductive coating for liquid crystal screens, flat screen devices, plasma screens, touch screens, and for applications related to electronic inks, organic light-emitting diodes, photovoltaic cells, antistatic deposits and shielding from electromagnetic interference. Methods for the deposition of thin ITO layers on a substrate comprise: cathode sputtering, thermal evaporation, pulsed laser deposition (PLD), chemical vapour deposition and the sol-gel method. However, these methods require sophisticated and/or expensive items of equipment due to the very high vacuum and/or the high temperature which they require. Moreover, the abovementioned methods do not make it possible to form microstructures and/or complex patterns on a substrate.

Furthermore, U.S. Pat. No. 5,281,447 describes a method for the preparation of a supported metal structure by application of an oxalate to a substrate and exposure of said oxalate to a source of energy, said oxalate corresponding to the following formula:

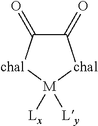

in which M is a metal from Group VIII, such as Ni, Pt, Os, Rh, Ru, Ir or Pd, chal is an oxygen, sulfur, selenium, or tellurium atom, Lₓ and L′_{y}, which are identical or different, are ligands based on sulfur or on one of the elements of Group Va (i.e. nitrogen, phosphorus, arsenic, antimony or bismuth), and x and y are equal to 0 or 1. The metal structure is produced using a mask or by using an energy beam which makes it possible to draw said structure according to the desired pattern. In particular, a solution of a palladium oxalate complex corresponding to the formula Pd(II)(oxalate)(CH₃CN)₂ dissolved in methanol is deposited on a non-metallic substrate and dried, in order to form a film on said substrate. The film is then exposed to an electron beam or to a filter-free Xe—Hg arc lamp and rinsed with a solvent in order to form a structure of palladium metal on said substrate. The presence of the ligands Lₓ and L′_{y} is described as essential in order to stabilize some of the complexes used, such as palladium(II) oxalate, in solid form or in solution, with regard to spontaneous decomposition. However, the presence of said ligands Lₓ and L′_{y} is not sufficient to stabilize some complexes, such as bis(phosphine)nickel oxalate. Furthermore, the conditions of preparation and of exposure of the oxalate film to an energy source are not optimized to manufacture shapes which are complex, patterns and/or microstructures exhibiting a good definition. This is because the use of a solution of the oxalate can bring about an uncontrolled crystallization of the oxalate in the form of large particles and/or of particles of heterogeneous sizes. Furthermore, the presence of nitrogenous ligands, such as (CH₃CN)₂, might lead, after exposure to an energy source, to the formation of undesirable phases. Finally, the energy sources used are not focused.

Alternative methods, such as screen printing, printed electronics or lithography, are studied in order to manufacture microstructures on a substrate, in particular in the field of microelectronics. However, they do not make it possible to form complex patterns while guaranteeing a structured and continuous deposit. Neither do they make it possible to use curved substrates.

Macroscopic or 3D parts can be produced by “additive manufacturing” processes. These processes make it possible to be freed from the design constraints related to the use of conventional machining techniques, which proceed by removing material and which can consequently be described as “subtractive”. They thus allow the production of novel parts having attractive aesthetic characteristics or having complex shapes, optimally providing the mechanical, electrical and/or magnetic properties desired. The additive manufacturing processes most widely used on the industrial scale include in particular 3D printing or binder jetting process (Three Dimensional Printing, 3DP), fused deposition modelling (FDM), the densification by laser of a plastic, ceramic or metal powder or of one of their mixtures (Selective Laser Sintering, SLS, or Selective Laser Melting, SLM), and the polymerization of a photosensitive liquid resin (Stereolithography/SL). In order to meet an increasingly great demand for functional parts and prototypes, the laser processes (SL, SLM and SLS) have achieved a degree of industrial development which is high and essential in many applicational fields. In particular, the SLS and SLM methods consist in locally sintering or melting a powder bed so as to draw, within it, the cutting plane of a part. By successively superimposing new powder beds on the first and by drawing, on each occasion, by laser, the upper cutting plane, it is thus possible to form a three-dimensional part. The mechanical strength of the latter is obtained by the sintering or the melting/solidification of the grains inside and at the interface of the superimposed powder layers. At the end of the operation, the powder which has not been irradiated by the laser is removed in order to release the part formed and to render it functional. The SLS and SLM methods generally employ powders, the chemical composition of which is very close, indeed even identical, to that of the constituent material of the final part. Mention may be made, for example, as materials dedicated to the manufacture by direct melting of the metal (SLM) and which are commercially available, of: stainless steel 316L, cobalt-chromium, Inconel 625 (alloy based on nickel and alloyed with chromium and iron) and titanium alloys (TiAl₆V₄). Nevertheless, the development of the SLM and SLS methods is limited by a restricted choice of the materials which can be used to manufacture metal or composite parts. This is because the material has to have a sufficient optical absorption at the wavelength of the laser used. In the contrary case, the beam may not sufficiently heat the grains of powders in order to cause them to sinter or to melt. The final part will thus not exhibit the desired mechanical characteristics or the targeted level of compactness. This problem can, in some cases, be solved either by the use of more powerful lasers, resulting in an increase in the cost of production of the part, or by changing the wavelength of the laser, which can also be the cause of different technical and economic problems. The SLS and SLM processes can even be ineffective with powders of refractory materials, when these powders have low optical absorptions.

Other difficulties may also be encountered, such as insufficient mechanical strength and/or the presence of discontinuities in the part manufactured. For example, additive manufacturing starting from ceramic powders generally results in porous parts, which do not exhibit the expected mechanical strength.

There thus exists a need for processes which make it possible to manufacture metal or composite parts in a simple and less expensive way and/or which employ materials which are easier to transform.

The aim of the present invention is thus to overcome the disadvantages of the abovementioned prior art and to provide a simple, implementationally easy and economic process which makes possible the manufacture of a metal, ceramic or composite part or of a supported metal, ceramic or composite microstructure, while guaranteeing better control of the surface states and of the textures and while preventing the presence of discontinuities and/or of heterogeneous porosity within said part or microstructure.

Another aim of the invention is to provide a metal, ceramic or composite microstructure supported by a substrate, said microstructure exhibiting a good adhesion to said substrate and being able to be used in varied applications, for example by creating, at the surface of a glass, an electrically conductive network, without significantly affecting its optical transparency, in order to obtain a transparent electrically conductive device.

Another aim of the invention is to provide a metal, ceramic or composite 3D part which exhibits good mechanical strength and which can be used in varied applications, in particular as micromagnet, electrical connector, antenna, coil or photonic, phononic, magneto-photonic or magnonic metamaterial.

A first subject-matter of the invention is thus a process for the manufacture of a metal, ceramic or metal-ceramic composite part or of a supported metal, ceramic or metal-ceramic composite microstructure, characterized in that it comprises at least the following stages:

i) the deposition of a suspension or of a powder of at least one metal oxalate, optionally as a mixture with one or more compounds resulting from the partial decomposition of said metal oxalate, on at least a portion of a surface of a solid substrate, in order to form a layer of said metal oxalate optionally as a mixture with said compound or compounds,

it being understood that:
the metal oxalate corresponds to the following formula (I):

M₂(C₂O₄)ᵥ.nH₂O (I)

in which:
M is a metal cation in the +v oxidation state (i.e. M^{v+}) or a mixture of metal cations with a +v mean oxidation state,
v is an integer such that 1≤v≤4,
n is such that n≥0, and preferably 0≤n≤8, and
the metal oxalate (I) (and the compound or compounds resulting from the partial decomposition of said metal oxalate, if they exist) of the suspension or of the powder is in the form of particles and/or of agglomerates of particles, with a mean size ranging from 10 nm to 100 μm approximately,

ii) the local heating of at least one zone of the layer of stage i), using a laser beam operating at a wavelength ranging from 150 nm to 2000 nm approximately, preferably from 150 nm to 1200 nm approximately and more preferably from 250 nm to 900 nm approximately, at a power density sufficient to irreversibly transform the layer of the locally heated zone into a metal, ceramic or metal-ceramic composite layer exhibiting a pattern corresponding to the heated zone,

iii) optionally removing the non-heated zones of the layer, and

iv) optionally the repetition, one or more times, of the sequence of stages i) to ii) or i) to iii), so as to form one or more new metal, ceramic or metal-ceramic composite layer(s) on at least a portion of a free surface of the solid substrate and/or on at least a portion of the preceding metal, ceramic or metal-ceramic composite layer.

Thus, the process of the invention is simple and economic. It makes it possible to result in a metal, ceramic or metal-ceramic composite part or microstructure starting from a suspension or from a powder comprising a metal oxalate which is easy to prepare, while guaranteeing better control of the surface states and of the textures and while preventing the presence of discontinuities and/or of heterogeneous porosity within said part or microstructure.

Stage i)

The metal cation M of the metal oxalate of formula (I) can be chosen from Ag⁺, Li⁺, Cu²⁺, Fe²⁺, Ni²⁺, Mn²⁺, Co²⁺, Zn²⁺, Mg²⁺, Sr²⁺, Ba²⁺, Sn²⁺, Ca²⁺, Cd²⁺, Fe³⁺, Cr³⁺, Bi³⁺, Ce³⁺, Al³⁺, Sb³⁺, Ga³⁺, In³⁺, Y³⁺, La³⁺, Am³⁺, Zr⁴⁺, Hf⁴⁺ and U⁴⁺.

The preferred metal cations are as follows: Ag⁺, Cu²⁺, Fe²⁺, Fe³⁺, Co²⁺, Ni²⁺, Bi³⁺ and Sn²⁺.

When M is a mixture of metal cations with identical or different oxidation state(s), +v, it can be a mixture of m metal cations M₁, . . . , Mₘ₋₁, Mₘ, each having an oxidation state +vᵢ, with 1≤i≤m, 2≤m≤7 and 1≤vᵢ≤4.

The water molecules, if they are present, are included in the structure of the metal oxalate of formula (I).

Furthermore, the metal oxalate of formula (I) of the suspension or of the powder is stable at ambient temperature.

It is the same for the compound or compounds resulting from the partial decomposition of said metal oxalate, if they exist.

The solid substrate can be opaque or transparent.

The solid substrate can be flexible or rigid.

The solid substrate can be flat or curved.

It can in particular be curved when it is a matter of forming a supported microstructure. In this case, the curvature should not prevent a homogeneous deposition of the suspension of metal oxalate of formula (I), optionally as a mixture with one or more compounds resulting from the partial decomposition of said metal oxalate. The acceptable value of the curvature will thus depend in particular on the characteristics of viscosity and of wettability of the suspension on the substrate considered.

The solid substrate can be made of glass, of metal (e.g. silicon), of glass-ceramic, of ceramic, of polymer or of any material which is resistant and/or inert with regard to the heating of stage ii) brought about by the laser beam.

The size of the solid substrate used in the process of the invention is not limiting.

By virtue of the use of at least one metal oxalate of formula (I), optionally as a mixture with one or more compounds resulting from the partial decomposition of said metal oxalate, in the form of a suspension or of a powder, the layer formed in stage i) is a continuous and homogeneous layer, in particular in the form of a film. This or these compounds resulting from the partial decomposition of said metal oxalate of formula (I) can be one or more metals M, alloyed or not, in the zero oxidation state, and/or one or more oxides of metals M, M being one or more metals of the metal cations M^{v+} of said oxalate.

In the present invention, the expression “partial decomposition of a metal oxalate (I)” means a reaction during which the metal oxalate (I) is partially transformed into one or more metals M, alloyed or not, in the zero oxidation state, and/or into one or more oxides of said metals M, M being one or more metals of the metal cations M^{v+} of said oxalate, in particular by heating at a temperature of at least 100° C. approximately.

When the compound or compounds resulting from the partial decomposition of said metal oxalate (I) are present in the suspension or the powder, they represent at most 75% by weight approximately and preferably at most 50% by weight approximately, with respect to the total weight of the metal oxalate (I) and of said compounds.

The layer formed in stage i) preferably exhibits a thickness ranging from 1 to 700 μm approximately, preferably ranging from 30 to 700 μm approximately and more preferably ranging from 30 to 500 μm approximately.

The layer of stage i) is a continuous layer. In other words, it does not exhibit discontinuities in patterns and/or surface irregularities and/or heterogeneities.

According to a specific embodiment, the layer formed in stage i) exhibits a roughness ranging from 1 to 5 μm approximately for an analytical surface area of 2.21 mm² approximately.

The layer of stage i) is preferably in direct physical contact with the solid substrate or a metal, ceramic or composite layer previously formed during a stage ii) when stage iv) exists.

Said metal oxalate of formula (I), and optionally the compound or compounds originating from the partial decomposition of said metal oxalate of formula (I), preferably represent(s) at least 80% by weight and more preferably at least 90% by weight approximately, with respect to the total weight of the layer.

According to a particularly preferred implementational form of the invention, the layer formed in stage i) comprises solely said metal oxalate of formula (I), optionally as a mixture with one or more compounds originating from the partial decomposition of said metal oxalate of formula (I) (i.e., said metal oxalate of formula (I) and optionally the compound or compounds originating from the partial decomposition of said metal oxalate of formula (I) represent(s) 100% by weight approximately, with respect to the total weight of the layer).

In the present invention, the expression “suspension of at least one metal oxalate of formula (I), optionally as a mixture with one or more compounds originating from the partial decomposition of said metal oxalate of formula (I),” means that the metal oxalate is in suspension in a liquid solvent, that is to say in the form of solid particles and/or of agglomerates of solid particles in said liquid solvent. The metal oxalate is thus not dissolved in said liquid solvent.

This is because, as explained above, the use of a solution of a metal oxalate (i.e., oxalate dissolved in a liquid solvent) does not make it possible to control its crystallization during the drying, resulting in the formation of large particles and/or of particles with heterogeneous sizes which are harmful for the implementation of the subsequent stage ii).

Thus, during stage i), the particles and/or agglomerates of particles of metal oxalate (I) of the powder or of the suspension do not undergo geometrical, morphological or structural modifications (e.g., no change in crystal structure and/or in dimensions) in order to form the metal oxalate layer.

The suspension can be a suspension of at least one metal oxalate of formula (I), optionally as a mixture with one or more compounds originating from the partial decomposition of said metal oxalate of formula (I), in a solvent chosen from polyols (e.g., ethylene glycol, propanediol, glycerol), simple alcohols (e.g., methanol, ethanol, propanol), tetrahydrofuran, dodecane, water and a mixture of at least two of the abovementioned solvents, if they are miscible.

According to a preferred implementational form, the suspension comprises from 20% to 80% by weight approximately and more preferably from 20% to 50% by weight approximately of said metal oxalate of formula (I), optionally as a mixture with one or more compounds originating from the partial decomposition of said metal oxalate of formula (I), with respect to the total weight of the suspension. The remainder of the suspension is generally a solvent as defined above.

According to a preferred implementational form of the invention, the suspension can additionally comprise one or more inert additives, the proportion of which advantageously varies from 1% to 10% by weight approximately, with respect to the total weight of the suspension.

Such inert additives can, for example, be adhesion agents, such as polyvinyl alcohol or polyvinylpyrrolidone.

In the present invention, the expression “inert additives” means that the additives do not affect the chemical process of the transformation of the metal oxalate (I) carried out during stage ii).

For example, the inert additives are different from reducing or oxidizing agents, such as those which can trigger a reaction for the oxidation/reduction of metal oxalates to give metal and/or metal oxide.

In the process of the present invention, it is the local heating as defined in stage ii) which makes it possible to directly transform the metal oxalate layer into a metal, ceramic or metal-ceramic composite layer.

In other words, no additive and/or agent, such as an initiating agent, is necessary to carry out this transformation of the metal oxalate layer.

The suspension can be prepared by mixing at least one metal oxalate of formula (I), optionally in the presence of one or more compounds originating from the partial decomposition of said metal oxalate of formula (I), and a solvent as defined above.

The mixing can be carried out in a mortar and/or using ultrasound (e.g., by placing the mixture in an ultrasonic bath). The ultrasound makes it possible to improve the dispersion of the metal oxalate (I) particles in the solvent.

The suspension preferably has a viscosity ranging from 30 to 300 cP approximately, said viscosity being measured at 25° C. approximately, using a rotational viscometer, such as an appliance sold under the trade name Rheomat 100 by the company Lamy Rheology.

When a suspension is used, stage i) is preferably carried out by depositing the suspension of the metal oxalate of formula (I), optionally as a mixture with one or more compounds originating from the partial decomposition of said metal oxalate of formula (I), on at least a portion of a surface of the solid substrate and by then drying said suspension. This thus makes it possible to form the layer of stage i).

This stage makes it possible to retain the benefit of the state of crystallization of the metal oxalate of formula (I), the latter having been prepared beforehand in the powder form (cf. stage i₀), and to hold on to a homogeneous particle size distribution of the metal oxalate of formula (I), optionally as a mixture with one or more compounds originating from the partial decomposition of said oxalate, within the layer formed in stage i), resulting in the formation of a homogeneous and continuous layer.

The deposition of the suspension on the solid substrate can be carried out by spin coating, spray coating or deep coating.

By way of example, the suspension can be deposited using an item of coating equipment (sometimes denoted “spinner”), in order to form a layer in the form of a film, or using a pipette, in order to spread the drops and to produce a smear.

After this deposition, the layer formed is dried in order to prevent the sudden evaporation of the solvent from the suspension during the following stage ii).

The drying can be carried out by evaporation at ambient temperature, by freeze-drying or by heating at a temperature ranging from 60° C. to 150° C. approximately. The drying generally lasts at least 3 hours, in order to prevent splitting of the deposit in the dry state and/or shrinkage cracks.

Freeze-drying is preferred.

When a suspension is used, the metal oxalate (I), optionally as a mixture with one or more compounds originating from the partial decomposition of said metal oxalate of formula (I), is preferably in the form of particles with a mean size ranging from 10 nm to 5 μm approximately and preferably from 100 nm to 1 μm approximately.

When a suspension is used, the layer formed in stage i) preferably exhibits a thickness ranging from 100 to 500 μm approximately.

When a powder is used, stage i) is preferably carried out by directly depositing the powder of the metal oxalate of formula (I), optionally as a mixture with one or more compounds originating from the partial decomposition of said metal oxalate of formula (I), on at least a portion of a surface of the solid substrate (e.g., manually or using an automatic system). This thus makes it possible to form the layer of stage i) in the form of a powder bed.

Stage i) is preferably carried out by spreading said powder over the solid substrate using a scraper, a knife or a roller or by deposition of said powder flowing through a hopper.

The deposition using a hopper, a scraper or a roller is preferred as it makes it possible to favour an even and continuous deposit.

When a powder is used, the metal oxalate (I), optionally as a mixture with one or more compounds originating from the partial decomposition of said metal oxalate of formula (I), is preferably in the form of particles and/or of agglomerates of particles with a mean size ranging from 1 to 100 μm approximately and more preferably from 3 to 20 μm approximately.

When a powder is used, the layer formed in stage i) preferably exhibits a thickness ranging from 30 to 100 μm approximately.

The suspension or the powder of stage i) can comprise several metal oxalates of formula (I), optionally as a mixture with one or more compounds resulting from the partial decomposition of said metal oxalates (I).

Stage i₀)

The process can additionally comprise, before stage i), a stage i₀) of preparation of at least one metal oxalate of formula (I) in the form of particles and/or of agglomerates of particles, with a mean size ranging from 10 nm to 100 μm.

On conclusion of this stage i₀), the metal oxalate can be used in stage i) either directly in the form of a powder or via the formation of a suspension, as indicated above.

Stage i₀) can be carried out by chemical precipitation, in particular by reacting a solution of at least one salt of metal cation M with oxalic acid or an oxalate soluble in said solution, M being as defined for the formula (I).

The oxalate soluble in the solution can be ammonium oxalate or sodium oxalate.

During stage i₀), the metal cations M of the salts used are precipitated by the oxalate anions C₂O₄²⁻ to form a metal oxalate of formula (I).

The salt of metal cation M can be a halide (e.g., chloride or bromide), a sulfate, a nitrate or an acetate.

The precipitation conditions which make it possible to prepare metal oxalates of various sizes and morphologies, in particular those of the invention, are well known to a person skilled in the art and are, for example, described in Tailhades, Thesis, 1988, Université Paul Sabatier.

A person skilled in the art knows how to adjust the reaction conditions of stage i₀), in order to form a metal oxalate having the desired particle size distribution (e.g. particles and/or agglomerates with a mean size ranging from 10 nm to 100 μm approximately, or from 1 to 100 μm approximately, or from 3 to 20 μm approximately, or from 10 nm to 5 μm approximately, or from 100 nm to 1 μm approximately).

Stage ii)

During stage ii), the heating brought about by the laser beam results in the decomposition of the metal oxalate of formula (I) to give a phase of metal or oxide type or to give a metal-oxide composite. This thus makes it possible to form a metal, ceramic or metal-ceramic composite layer in the irradiated or heated zone. The decomposition which takes place in stage ii) is an irreversible transformation.

In particular, following the absorption of a portion of the energy contributed by the laser beam, the metal oxalate decomposes to result in the formation of highly reactive nanoparticles, the propensity of which for sintering is great since their melting point is generally lowered with respect to the bulk state.

Thus, during stage ii), the metal cations M of the layer can be either completely reduced, to form a metal phase, or partially or completely brought to an oxidation state greater than or equal to the oxidation state +v of the metal in the metal oxalate of formula (I), to form an oxide phase (i.e., ceramic layer), or both, to form a metal-oxide (i.e., metal-ceramic) composite layer.

The metal, ceramic or composite layer formed in stage ii) can thus consist of one or more metals, of one or more alloys of metals, of a simple or mixed metal oxide, or of an oxide-metal composite.

Stage ii) can be carried out at a power density ranging from 0.1×10⁶ to 10×10⁶ W/cm² approximately, and preferably from 0.1×10⁶ to 6×10⁶ W/cm² approximately.

Thus, the process of the invention is simple and economical in view of the use of moderate laser power densities.

This is because the inventors of the present patent application have discovered that the decomposition of the metal oxalate of the layer formed in stage i) can be carried out under a laser beam of low power density (e.g., <10⁷ W·cm⁻²), in contrast to the materials used in the prior art, which require high power densities.

Typically, the photolithography machines very widely used in the field of microelectronics can be used in stage ii) of the process of the invention to form metal, ceramic or composite parts or microstructures starting from a layer of a metal oxalate of formula (I), optionally as a mixture with one or more compounds originating from the partial decomposition of said oxalate, even if the laser beams which they use only deliver a power of the order of a few tens of milliwatts, focused on a surface area in the region of a micrometre.

According to a specific embodiment of the process of the invention, stage ii) is carried out by causing the layer-solid substrate assembly from stage i) to progress forward, with respect to the laser beam, at a “displacement” rate ranging from 0.1 to 3000 mm·s⁻¹ approximately.

According to a preferred implementational form, stage ii) is carried out by positioning the focal point of the laser beam at the interface of solid substrate and of layer of a metal oxalate, optionally as a mixture with one or more compounds originating from the partial decomposition of said oxalate.

Preferably, stage ii) is carried out with a laser beam exhibiting a diameter ranging from 1 to 70 μm approximately, preferably from 1 to 20 μm and more preferably from 1 to 10 μm.

The duration of stage ii) is defined by the scanning rate of the laser beam, which preferably ranges from 0.1 to 5000 mm/s, and the diameter of the laser beam. For example, for a laser beam with a diameter of 70 μm and a rate of 2500 mm/s, the irradiation time is 2.8×10⁻⁵ s.

Stage ii) can, for example, be carried out using an appliance comprising a semiconductor laser (laser diode), a solid laser or a gas laser, and preferably a solid laser.

Mention may be made, as examples of lasers suitable in the present invention, of laser diodes or solid lasers, such as Nd:YAG or titanium-sapphire lasers.

Mention may be made, as example of appliance which can be used, of a conventional lithography appliance or of an additive manufacturing machine which can deliver a power density ranging from 0.1×10⁶ to 10×10⁶ W/cm² approximately, in particular with a laser diode emitting at 405 nm or an Nd:YAG solid laser emitting at 1.07 μm.

In the present invention, the expression “heating using a laser beam” also means laser irradiation.

During stage ii), the laser irradiation follows a design (or pattern) programmed beforehand in a system for controlling the laser appliance used. This design can correspond either to the first cutting plane of the part to be produced or to the final geometry of two-dimensional patterns of the microstructure to be produced.

The pattern of the layer formed in stage ii) is variable and can in particular be a criss-cross pattern, a rectangle, a square, a straight line, a curved line or any other shape desired.

Stage ii) is preferably carried out at atmospheric pressure.

Stage ii) can be carried out in the air, under an inert atmosphere, such as an atmosphere of nitrogen, of argon or of helium, or a reducing atmosphere, such as a mixture of argon or of nitrogen with molecular hydrogen in proportions which, preferably, will not give a dangerous atmosphere (e.g., 3.9% by volume of molecular hydrogen).

Depending on the type of metal used for the oxalate of formula (I) (e.g., silver) and its thickness, the layer formed in stage ii) may be not very absorbing with regard to the laser beam.

Stage ii) can be carried out several times before stage iii) or after stage iii), in particular in order to heat several times the zone (or at least a portion of the zone) already irradiated a first time.

Stage ii) can be repeated with a power density identical to or greater than that of the preceding stage ii).

Stage ii) can also be carried out according to the following series: laser irradiation of the zone along a transverse axis (0,y) and then laser irradiation of the zone along a longitudinal axis (0,x). This series can be carried out several times, in particular with a power density identical to or greater than that of the preceding stage ii).

When stage ii) is carried out several times, the power of the laser beam can be gradually increased after each laser irradiation, or after each series of laser irradiations or after several (e.g., two or three) series of laser irradiations.

When stage ii) is carried out several times on the same zone, this makes it possible to improve the cohesion and/or the mechanical strength of the layer formed in stage ii). This embodiment is particularly appropriate when it is desired to manufacture a metal, ceramic or metal-ceramic composite part.

Stage iii)

Stage iii) can be carried out by washing, by dissolution or by suction.

Stage iii) thus makes it possible to remove the metal oxalate which has not been irradiated during stage ii), while guaranteeing that the metal, ceramic or metal-ceramic composite layer formed during stage ii) is not damaged.

Washing or suction is particularly suitable when stage i) is carried out by deposition of a metal oxalate of formula (I), optionally as a mixture with one or more compounds originating from the partial decomposition of said oxalate, in the form of a powder.

Washing can be carried out using ultrasound or a flow of inert liquid (e.g., jet of water).

Dissolution can be carried out using a dissolution agent or a supercritical fluid.

Dissolution is particularly suitable when stage i) is carried out by deposition of a metal oxalate of formula (I) in the form of a suspension.

Preferably, the dissolution agent is chosen from an aqueous ammonia solution or an aqueous solution of strong acid (e.g., hydrochloric acid or sulfuric acid), in particular at a concentration which makes it possible to dissolve the oxalate or oxalates without strongly attacking the metal oxides and/or the metals formed in the irradiated zones.

The aqueous ammonia solution can have a molar concentration of ammonia of 0.5 to 4 mol/l approximately.

The supercritical fluid can be supercritical CO₂.

Stage iii) can also be carried out using a sacrificial layer.

The sacrificial layer technique is well known to a person skilled in the art, in particular in the field of microelectronics, and consists of the selective dissolution of the “sacrificial” layers facing the structural layers, which will be retained after said dissolution.

When stage iv) exists, one or more new metal, ceramic or metal-ceramic composite layer(s) are formed on at least a portion of a free surface of the solid substrate (i.e., a portion of a surface of the substrate which has not already been covered with a layer during a preceding stage ii) and/or on at least a portion of the preceding metal, ceramic or metal-ceramic composite layer.

Stage iv) is carried out using a powder of metal oxalate of formula (I), optionally as a mixture with one or more compounds originating from the partial decomposition of said metal oxalate of formula (I), when stage iv) consists in forming one or more new metal, ceramic or metal-ceramic composite layer(s) on at least a portion of the preceding metal, ceramic or metal-ceramic composite layer.

Stage iv) is carried out using a powder or a suspension of metal oxalate of formula (I), optionally as a mixture with one or more compounds originating from the partial decomposition of said metal oxalate of formula (I), when stage iv) consists in forming one or more new metal, ceramic or metal-ceramic composite layer(s) on at least a portion of a free surface of the solid substrate.

Manufacture of a Supported Microstructure

According to a first embodiment of the invention, the metal, ceramic or metal-ceramic composite layer formed in stage ii) and the metal, ceramic or metal-ceramic composite layers formed in stage iv), if stage iv) exists, are not separated from the solid substrate and form a supported microstructure.

The process thus results in the manufacture of a metal, ceramic or metal-ceramic composite microstructure deposited on a solid substrate (i.e., a supported microstructure). The metal, ceramic or metal-ceramic composite microstructure consists of the metal, ceramic or metal-ceramic composite layer formed in stage ii) or of the metal, ceramic or metal-ceramic composite layers formed in stages ii) and iv).

Stage iv) can be carried out at least once in order to form a new metal, ceramic or metal-ceramic composite layer exhibiting a pattern corresponding to the zone heated on a free portion of the surface of the solid substrate. The pattern formed in stage iv) can be different from that of stage ii).

According to a particularly preferred implementational form of this first embodiment, the solid substrate is a transparent substrate and the metal cation of the metal oxalate (I) used in stage i) is a cation of a conductive metal, such as silver or copper.

The microstructure formed in stage iii) or iv) can have a thickness ranging from 1 μm to 200 μm approximately.

Manufacture of a Part

According to a second embodiment of the invention, the process comprises stage iv) and the metal, ceramic or metal-ceramic composite layers formed in stages ii) and iv) form a part which is separated from the solid substrate according to a stage v) (self-supported part).

The process thus results in the manufacture of a metal, ceramic or metal-ceramic composite part. The metal, ceramic or metal-ceramic composite part consists of the metal, ceramic or metal-ceramic composite layers formed in stages ii) and iv).

This is because, in order to produce a three-dimensional part, the use of stage iv) makes it possible to link together a series of cycles consisting in depositing a layer of metal oxalate on at least a portion of its pre-irradiated homologue and then drawing a new cutting plane by the laser beam on this additional layer. This series of cycles is reproduced a sufficient number of times to construct the desired part in its entirety.

Stages iv) can be carried out while changing the nature of the metal oxalate, so as to form layers of different natures.

Stage v) can be carried out by cutting or chopping.

Stage vi)

The process can additionally comprise a stage vi) of heat treatment of the part or of the microstructure formed in stage ii), iii), iv) or v).

This stage vi) makes it possible to improve the sintering.

Stage vi) can be carried out at a temperature ranging from 400° C. to 1500° C. and preferably ranging from 500° C. to 1000° C.

According to a preferred implementational form, stage vi) is carried out using a furnace having heating elements, in particular resistive heating elements, a lamp furnace, an inductive furnace or a microwave furnace.

The process can additionally comprise, after any one of stages ii), iii), iv) or v), a stage vii) of treatment of its surface.

The process can additionally comprise, after any one of stages ii), iii), iv) or v), a stage viii) of deposition of a metal or ceramic coating by an electrochemical, electrophoresis, chemical vapour deposition, sol-gel deposition, and the like, process.

Stages vi), vii) and viii) are finishing stages, in particular carried out in order to relax the residual mechanical stresses, to adjust the oxidation/reduction state, to carry out a crystal phase change, to improve the surface properties (hardness, resistance to corrosion, attractiveness, and the like) and/or to introduce any other functionality of use in the technological application of the part or of the supported microstructure.

Thus, the process of the invention, which resorts to metal oxalates of formula (I), optionally as a mixture with one or more compounds originating from the partial decomposition of said oxalates, makes it possible to significantly lower the laser power necessary for the manufacture of said parts or supported microstructures. It makes it possible to manufacture parts or supported microstructures based on metals or on metal oxides which are generally difficult to sinter or to melt by conventional SLS or SLM additive manufacturing. Thus, the process can use appliances having less powerful, less energy-consuming and less expensive lasers.

Furthermore, the process of the invention guarantees better control of the surface states and of the textures, while preventing the presence of discontinuities and/or of heterogeneous porosity within said part or microstructure.

A second subject-matter of the invention is a metal, ceramic or composite microstructure supported by a solid substrate, said microstructure comprising at least one metal M chosen from the metals of the metal cations M^{v+} as defined for the formula (I), characterized in that it is capable of being obtained by the process in accordance with the first subject-matter of the invention.

In particular, the metal M can be chosen from Ag, Li, Cu, Fe, Ni, Mn, Co, Zn, Mg, Sr, Ba, Sn, Ca, Cd, Cr, Bi, Ce, Al, Sb, Ga, In, Y, La, Am, Zr, Hf and U, and preferably from Ag, Cu, Fe, Co, Ni, Bi and Sn.

The solid substrate can be as defined in the first subject-matter of the invention.

A third subject-matter of the invention is a metal, ceramic or composite part comprising at least one metal M chosen from the metals of the metal cations M^{v+} as defined for the formula (I), characterized in that it is capable of being obtained by the process in accordance with the first subject-matter of the invention.

In particular, the metal M can be chosen from Ag, Li, Cu, Fe, Ni, Mn, Co, Zn, Mg, Sr, Ba, Sn, Ca, Cd, Cr, Bi, Ce, Al, Sb, Ga, In, Y, La, Am, Zr, Hf and U, and preferably from Ag, Cu, Fe, Co, Ni, Bi and Sn.

The sudden decomposition of the metal oxalate (I) under the effect of a laser beam (stage ii)), followed by a rapid cooling, can result in the formation of novel alloys or oxides, in particular of metastable phases. This is because the metastability can result from the conditions, very distant from thermodynamic equilibrium, under which they are formed. Furthermore, the passage, during the decomposition of the metal oxalate (I), by the creation of nanometric grains, can cause specific microstructures (mesoporosity, for example) in the final part or microstructure.

In particular, the part or the supported microstructure obtained by the process of the invention exhibits a micronic or submicronic porosity which is very homogeneously distributed. The porosity can be between 10% and 80% by volume approximately, it being possible for the mean size of the pores to be between 100 nm and 5 μm approximately. Furthermore, the part or the supported microstructure can comprise traces of carbon.

The parts and supported microstructures obtained by the process of the invention are consequently different from those prepared in the prior art starting from powders of metals or of oxides, the composition and even the crystal structure of which are identical to those of the finished product (constituent material of the final part or microstructure). They consequently can provide different functionalities and can meet technological needs not currently satisfied.

A fourth subject-matter of the invention is the use of a supported microstructure obtained according to the process in accordance with the first subject-matter of the invention as transparent conductive material, in particular in the fields of optics, photovoltaics or transparent electronics; as electrical connector; as two-dimensional metamaterial of photonic, magneto-photonic or magnonic type; or as microfluidic system, in particular in the field of biology or diagnostics.

A fifth subject-matter of the invention is the use of a part obtained according to the process in accordance with the first subject-matter of the invention as antenna, coil, micromagnet, metamaterial having a forbidden band of photonic, phononic, magneto-photonic or magnonic type, or as part of complex shape.

In particular, the part of the invention can be used as part of complex shape necessary for the cohesion of a structure (e.g., chassis, flange) or exerting a mechanical function (small turbines, propellers).

The part or the supported microstructure can also be used in the field of luxury objects, of decorative art objects or of costume jewellery.

### EXAMPLES

Example 1: Manufacture of a Metal Microstructure Having Periodic Patterns According to the Process in Accordance with the Invention A silver oxalate corresponding to the formula Ag₂C₂O₄ and in the form of a powder of acicular particles with a mean length of 5 μm approximately and with a mean width of 1 μm was prepared according to the procedure described in K. Kiryukhina et al., Scripta Materialia, 2013, 68, 623-626.

1 g of this oxalate was mixed with 4 g of ethylene glycol in an agate mortar. The resulting mixture was subsequently placed in an ultrasonic bath in order to provide good dispersion of the particles in the ethylene glycol. The viscosity of the mixture was 32 cP approximately and was measured under the conditions as defined in the present invention.

3 drops (approximately 1.5 ml in volume) of the suspension obtained above were deposited on a glass slide with dimensions of 3 cm×2.5 cm as substrate, in order to produce a smear. The assembly was placed in a freeze-drying device sold under the trade name Alpha2-4 by the company Christ in order to make possible the evaporation of the ethylene glycol. The compartment of the freeze dryer including the sample was brought from atmospheric pressure down to 10⁻³ mbar approximately in 3 hours approximately, in order to avoid the splitting of the deposit in the dry state. The temperature was 25° C. approximately throughout the operation. After bringing back to atmospheric pressure, the layer of silver oxalate deposited on the glass slide had a thickness of approximately 300 μm.

The glass slide comprising the layer of silver oxalate was subsequently placed in a laser lithography device sold under the trade name Dilase 250 by the company Kloé. Laser irradiation was carried out while adjusting the focus of a laser diode with a wavelength of 405 nm at the glass slide/layer of silver oxalate interface. The diameter of the laser beam was 2 μm approximately, the rate of displacement of the sample under the laser beam was 5 mm·s⁻¹ approximately and the power density of the laser was 0.16×10⁶ W/cm² approximately.

The pattern to be irradiated was a grid of 200×200 μm² and was preprogrammed on the lithography device.

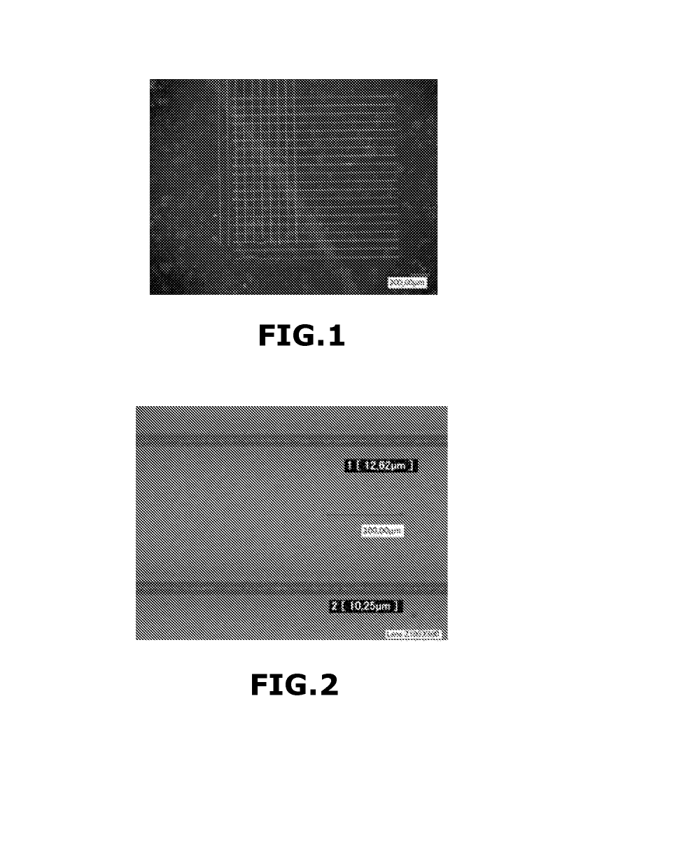

Subsequently, the sample was placed in a 4 mol/l aqueous ammonia solution in order to dissolve the silver oxalate present in the zones which were not irradiated. All that remains on the glass slide is a grid of silver metal comprising silver wires with a width of 12 μm approximately and with a thickness of 3 to 5 μm approximately. This is because, during the laser irradiation stage, the silver oxalate has been reduced to silver metal in the irradiated zones. FIG. 1 shows an image of the supported microstructure obtained by the process of the invention, said microstructure being in the form of a grid of silver metal.

The microstructure obtained was transparent.

### Example 2: Manufacture of a Metal Microstructure Having Periodic Patterns According to the Process in Accordance with the Invention

The microstructure obtained according to Example 1 was heated up to a temperature of 300° C. approximately at a heating rate of 150° C./h approximately using a furnace having heating elements. The microstructure was maintained at 300° C. for 1 h and was then cooled down to ambient temperature at a cooling rate of 150° C./h approximately. This additional stage made possible the sintering of the silver wires as obtained in Example 1. A grid of silver metal comprising silver wires with a width of 10 μm approximately and with a thickness of 5 μm approximately was thus obtained.

The microstructure obtained remained transparent.

### Example 3: Manufacture of a Metal Microstructure Having a Linear Pattern According to the Process in Accordance with the Invention

A microstructure was prepared under the same conditions as those described in Example 1, except as regards the rate of displacement of the sample, which was 1 mm/s instead of 5 mm/s, and the pattern to be irradiated, which was a line with a length of 15 mm instead of a grid of 200×200 pmt.

Furthermore, ten successive passes were carried out according to said pattern without stage iii) (i.e., without removal of the layer in the unheated zones).

A line of silver metal with a width of 15 μm approximately and with a thickness of approximately 5 μm was thus obtained.

The electrical conductivity of this line was determined by the two-point method using a multimeter of the Keithley trademark, and was 7.5×10⁵ S·m⁻¹ approximately.

Thus, the process of the invention makes it possible to confer an electrical conductivity on a glass substrate while retaining its optical transparency.

### Example 4: Manufacture of a Metal Microstructure Having a Linear Pattern According to the Process in Accordance with the Invention

A copper oxalate corresponding to the formula CuC₂O₄.0.5H₂O and in the form of a powder of grains with a length of 40 nm approximately and with a diameter of 25 nm approximately was prepared according to the procedure described in V. Baco-Carles et al., ISRN Nanotechnology, 2011, Article ID 729594, doi:10.5402/2011/729594, 7 pages).

1 g of this oxalate was mixed with 4 g of water in an agate mortar. The resulting mixture was subsequently placed in an ultrasonic bath in order to provide good dispersion of the particles in the water. The resulting suspension was deposited on a silicon substrate in the form of a film using an item of coating equipment sold under the “spin coater” trade name by the company Suss and operating at a rotational speed of 3000 rev/min approximately. The thickness of the film obtained was 1 μm approximately. The items of coating equipment (sometimes denoted “spinners”) are very common items of equipment sold by different companies.

The substrate comprising the layer of copper oxalate was subsequently placed in the laser lithography device as described in Example 1. Laser irradiation was carried out while adjusting the focus of a laser with a wavelength of 405 nm at the glass slide/layer of copper oxalate interface. The diameter of the laser beam was 2 μm approximately, the rate of displacement of the sample under the laser beam was 0.5 mm·s⁻¹ approximately and the power density of the laser was 0.16×10⁶ W/cm² approximately.

The pattern to be irradiated was lines with a length of 5 mm and was preprogrammed on the lithography device.

After the irradiation stage, lines of copper metal partially oxidized at the surface with a width of 10 to 12 μm approximately were formed on the substrate. This is because, during the laser irradiation stage, the copper oxalate was reduced to copper metal partially oxidized at the surface in contact with the air in the irradiated zones. FIG. 2 shows an image of the supported microstructure obtained by the process of the invention, said microstructure being in the form of lines of copper metal partially oxidized at the surface.

### Example 5: Manufacture of a Metal Microstructure Having a Linear Pattern According to the Process in Accordance with the Invention

A copper oxalate in the form of a powder composed of isotropic particles with a mean diameter of 3 μm approximately was prepared by modifying the precipitation conditions described in V. Baco-Carles et al., ISRN Nanotechnology, 2011, Article ID 729594, doi:10.5402/2011/729594, 7 pages, and in Tailhades, Thesis, 1988, Université Paul Sabatier. An aqueous solution of copper nitrate Cu(NO₃)₂.2.5H₂O (98.5%, Alfa Aesar) with a concentration of 2M was then precipitated with an aqueous solution of ammonium oxalate (NH₄)₂C₂O₄.H₂O (98% Laurylab) with a concentration of 0.4M.

1 g of this oxalate was mixed with 4 g of ethylene glycol in an agate mortar. The resulting mixture was subsequently placed in an ultrasonic bath in order to provide good dispersion of the particles in the ethylene glycol.

The suspension was deposited on a glass slide and dried as in example 1. The glass slide comprising the layer of copper oxalate was subsequently placed in the laser lithography device as described in Example 1. Laser irradiation was carried out while adjusting the focus of a laser with a wavelength of 405 nm at the glass slide/layer of copper oxalate interface. The diameter of the laser beam was 2 μm approximately, the rate of displacement of the sample under the laser beam was 0.5 mm·s⁻¹ approximately and the power density of the laser was 0.16×10⁶ W/cm² approximately.

The pattern to be irradiated was a line with a length of 5 mm and was preprogrammed on the lithography device.

Lines of copper metal and/or of re-oxidized copper with a width of 10 μm approximately were formed.

### Example 6: Manufacture of a Ceramic Microstructure Having a Rectangular Pattern According to the Process in Accordance with the Invention

An iron oxalate corresponding to the formula FeC₂O₄.2H₂O and in the form of a powder of acicular particles with a mean length of 0.5 μm and with a width of 50 nm was prepared according to the procedure described in Tailhades, Thesis, 1988, Université Paul Sabatier.

1 g of this iron oxalate was mixed with 4 g of ethylene glycol in an agate mortar. The resulting mixture was subsequently placed in an ultrasonic bath in order to provide good dispersion of the particles in the ethylene glycol.

The suspension was deposited on a glass slide and dried as in Example 1. The glass slide comprising the layer of iron oxalate was subsequently placed in the laser lithography device as described in Example 1. Laser irradiation was carried out while adjusting the focus of a laser with a wavelength of 405 nm at the glass slide/layer of iron oxalate interface. The diameter of the laser beam was 2 μm approximately, the rate of displacement of the sample under the laser beam was 1 mm·s⁻¹ approximately and the power density of the laser was 0.41×10⁶ W/cm² approximately.

The pattern to be irradiated was a rectangular zone with dimensions of 18 mm×15 mm and was preprogrammed on the lithography device.

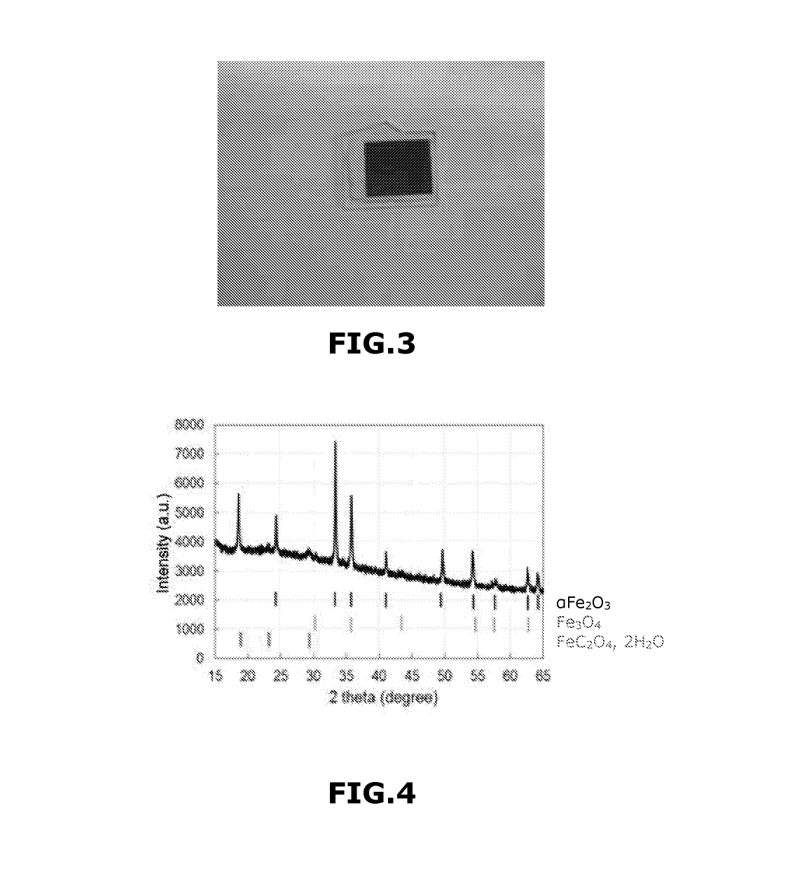

The irradiated layer was analysed by X-ray diffraction (XRD) using an appliance sold under the trade name D4 by the company Brucker. FIG. 3 shows an image of the supported microstructure obtained by the process of the invention, said microstructure being in the form of a layer based on iron oxide.

The XRD analysis showed the presence of a predominant αFe₂O₃ phase. Traces of magnetite Fe₃O₄ and of iron oxalate were also observed, as is shown by FIG. 4.

### Example 7: Manufacture of a Ceramic Microstructure Having a Pattern According to the Process in Accordance with the Invention

A mixed iron cobalt oxalate corresponding to the formula CoFe₂(C₂O₄)₃ and in the form of a powder of acicular particles with a mean length of 1 μm approximately and with a mean width of 0.3 μm was prepared according to the procedure described in Le Trong H. et al., Solid State Sciences, 2008, 10(5), 550-556.

1 g of this oxalate was mixed with 4 g of ethylene glycol in an agate mortar. The resulting mixture was subsequently placed in an ultrasonic bath in order to provide good dispersion of the particles in the ethylene glycol.

The suspension was deposited on a glass slide and dried as in Example 1. The glass slide comprising the layer of iron cobalt oxalate was subsequently placed in the laser lithography device as described in Example 1. Laser irradiation was carried out while adjusting the focus of a laser with a wavelength of 405 nm at the glass slide/layer of iron cobalt oxalate interface. The diameter of the laser beam was 2 μm approximately, the rate of displacement of the sample under the laser beam was 1 mm·s⁻¹ approximately and the power density of the laser was 0.64×10⁶ W/cm² approximately.

The pattern to be irradiated was a rectangle with dimensions of 18×15 mm² and was preprogrammed on the lithography device.

A layer having a rectangular pattern, the structure of which was analysed by X-ray diffraction (XRD) using an appliance as described in Example 6, was formed.

The XRD analysis showed the presence of a spinel phase. This is because the diffractogram is characteristic of a spinel phase of CoFe₂O₄ type and of a monoxide phase of CoO type. The magnetic measurements carried out with a VSM device of Versalab model and of the Quantum Design trademark showed the presence of a ferrimagnetic phase. The coercive field was 1630 Oe at 300 K. After cooling, under a field of 3 T, from ambient temperature down to 100 K, the coercive field reached a very high value of 6130 Oe at 100 K. The hysteresis cycle was offset on the axis of the abscissae (exchange field of 1650 Oe), revealing a strong magnetic coupling between the spinel phase and the monoxide. This strong coupling also testifies to the intimate coexistence of these phases at the nanometric scale.

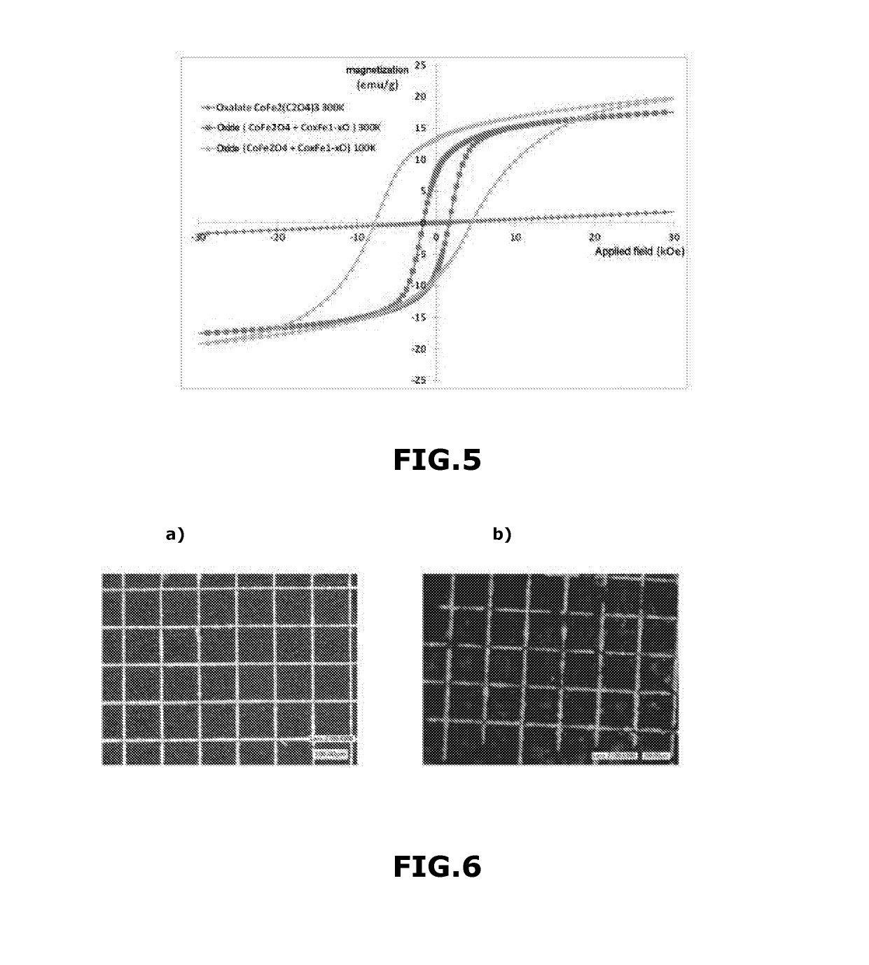

FIG. 5 represents the curves of the magnetization M (in emu/g) of the oxalate of formula (I) CoFe₂(C₂O₄)₃ at 300 K (curve with the solid diamonds) and of the compounds obtained after irradiation at 300 K (curve with the solid squares) and 100 K (curve with the solid triangles), as a function of the magnetic field H (in KOe).

### Example 8: Manufacture of a 3D Part According to the Process in Accordance with the Invention

A suspension of silver oxalate in ethylene glycol was prepared, deposited on a glass slide and dried under the conditions as described in Example 1. The sample obtained was subsequently irradiated while adjusting the focus of a laser with a wavelength of 405 nm at the glass slide/layer of silver oxalate interface. The diameter of the laser beam was 2 μm approximately and the rate of displacement of the sample under the laser beam was 1 mm·s⁻¹ approximately.

Formation of a First Layer

A first pattern forming a square with dimensions of 5 mm×5 mm was irradiated over the whole of its surface at a power density of 0.16×10⁶ W/cm². The irradiation was carried out line-by-line along a longitudinal axis (0,x).

Then, inside this zone, a second square of 3 mm×3 mm was irradiated over the whole of its surface, along a transverse axis (0,y), at a power density of 0.22×10⁶ W/cm², and then along a longitudinal axis (0,x), still at a power density of 0.22×10⁶ W/cm².

At this stage, the excess of non-irradiated material located outside the zone treated by the laser was removed.

The sample was subsequently placed back in the lithography device in order to carry out an irradiation of the second square of 3 mm×3 mm while gradually increasing the power density of the laser (0.32×10⁶ W/cm², 0.64×10⁶ W/cm², 1.6×10⁶ W/cm² and 2.7×10⁶ W/cm²) at the end of each irradiation series carried out alternately along the axis (0,x) and then the axis (0,y). For each power used, 2 scans were carried out.

On conclusion of these irradiation sequences, a well-defined square of silver was obtained which exhibits good adhesion to the glass substrate.

Formation of a Second Layer

Silver oxalate powder as used in Example 1 was subsequently added and compacted using a scraper and the application of a manual force to the square pattern of 5 mm×5 mm.

The powder thus deposited was then irradiated three times as above to form a square of 3 mm×3 mm, while still alternating a longitudinal scanning (0,x) at a power density of 0.16×10⁶ W/cm² on the square of 5 mm×5 mm, and then a transverse scanning (0,y) followed by a longitudinal scanning (0,x) at a power density of 0.22×10⁶ W/cm² on the square of 3 mm×3 mm. The non-irradiated powder was subsequently removed.

The sample was subsequently placed back in the lithography device in order to carry out an irradiation of the second square of 3 mm×3 mm while gradually increasing the power of the laser (0.32×10⁶ W/cm², 0.64×10⁶ W/cm², 1.6×10⁶ W/cm², 2.7×10⁶ W/cm² and 3.2×10⁶ W/cm²) at the end of each irradiation series carried out alternately along the axis (0,x) and then the axis (0,y). For each power used, 4 scans were carried out.

Formation of a Third Layer and then of a Fourth Layer

The operations for the second layer were reproduced for the third and fourth layers. On conclusion of these different stages, a 3D object with a thickness in the region of 600 μm approximately was obtained. This object consisted of pure silver metal, the sintering of which resulting from the irradiation by the laser beam provides the mechanical strength. The analysis by X-ray diffraction confirmed that silver metal was obtained.

### Example 9: Manufacture of a Metal Microstructure Having Periodic Patterns According to the Process in Accordance with the Invention

The silver oxalate used in Example 1 was partially decomposed by heating it at 120° C. approximately in an oven for 20 hours approximately.

1 g of this partially decomposed silver oxalate was mixed with 4 g of ethylene glycol in an agate mortar. The resulting mixture was subsequently placed in an ultrasonic bath in order to provide good dispersion of the particles in the ethylene glycol.

The suspension was deposited on a glass slide and dried as in Example 1.

The glass slide comprising the layer of partially decomposed silver oxalate was subsequently placed in the laser lithography device. Laser irradiation was carried out while adjusting the focus of a laser with a wavelength of 405 nm at the glass slide/layer of partially decomposed silver oxalate interface. The diameter of the laser beam was 2 μm approximately, the rate of displacement of the sample under the laser beam was 1 mm·s⁻¹ approximately and the power density of the laser was 0.22×10⁶ W/cm² approximately.

The pattern to be irradiated was lines with a length of 5 mm and was preprogrammed on the lithography device. Lines of silver metal with a mean width of 10 μm were obtained.

### Comparative Example 10: Manufacture of a Metal Microstructure According to a Process not in Accordance with the Invention

1 g of silver nitrate was mixed respectively with 1 g (mixture A) and 4 g (mixture B) of ethylene glycol in an agate mortar. The resulting mixtures A and B were respectively in the form of a colourless suspension A and of a colourless solution B (solubility limit of silver nitrate in ethylene glycol: 49.67 g per 100 g of ethylene glycol at 20° C. approximately).

The abovementioned mixtures A and B were stored at 5° C. in order to prevent a change in colouration (from colourless to black) after a few hours.

3 drops of the suspension A obtained above (respectively 3 drops of the solution B obtained above) were deposited on a glass slide with dimensions of 3 cm×2.5 cm as substrate, in order to produce a smear. The assembly was placed in a freeze-drying device sold under the trade name Alpha2-4 by the company Christ in order to make possible the evaporation of the ethylene glycol. The compartment of the freeze dryer including the sample was sheltered from the light and brought from atmospheric pressure down to 10⁻³ mbar approximately in 3 hours approximately. The temperature was 25° C. approximately throughout the operation. After bringing back to atmospheric pressure, the two deposits of silver nitrate deposited on the glass slide did not form a continuous layer and exhibited in particular surface heterogeneities.

The glass slide comprising the deposit resulting from the solution B (respectively comprising the deposit resulting from the suspension A) was subsequently placed in a laser lithography device as described in Example 1. Laser irradiation was carried out while adjusting the focus of a laser with a wavelength of 405 nm at the glass slide/deposit of silver nitrate interface. The diameter of the laser beam was 2 μm approximately, the rate of displacement of the sample under the laser beam was 0.5 mm·s⁻¹ approximately and the power density of the laser was 0.9×10⁶ W/cm² approximately.

The pattern to be irradiated was a grid of 200×200 μm² for the deposit resulting from the solution B and that resulting from the suspension A, and was preprogrammed on the lithography device.

Subsequently, the samples were placed in a 4 mol/l aqueous ammonia solution in order to dissolve the silver nitrate present in the zones which were not irradiated.

For the deposit resulting from the solution B, all that remains on the glass slide is a grid of silver metal comprising silver wires with a width of 9-15 μm approximately. FIG. 6 shows an image of the supported microstructure obtained by a process in accordance with the invention by replacing the solution B with a suspension of a silver oxalate and obtained according to the same irradiation conditions as those described above (FIG. 6a) and, by comparison, an image of the supported microstructure obtained by a process not in accordance with the invention and as described above (FIG. 6b). The microstructure of FIG. 6b is in the form of a grid of silver metal exhibiting numerous surface heterogeneities and discontinuities. Furthermore, observations by optical microscopy have shown, before treatment with ammonia, the formation of patterns of irregular dimensions due to strong surface heterogeneities observed, and to strong transformation heterogeneities.

For the deposit resulting from the suspension A, the treatment with ammonia did not make it possible to preserve the irradiated structure. Furthermore, observations by optical microscopy have shown, before treatment with ammonia, formed patterns very poorly defined due to strong surface heterogeneities observed, and to strong transformation heterogeneities.

### Comparative Example 11: Manufacture of a Metal Microstructure According to a Process not in Accordance with the Invention

A solution of silver oxalate was prepared by recovering the supernatant from a suspension prepared under the same conditions as those described in Example 1 and separated by settling for 7 days.

The molar concentration of silver oxalate was extremely dilute, i.e. 0.025 mol/l approximately (i.e., a concentration by weight of 0.7%).

3 drops of the solution obtained above were deposited on a glass slide with dimensions of 3 cm×2.5 cm as substrate, in order to produce a smear. The assembly was placed in a freeze-drying device sold under the trade name Alpha2-4 by the company Christ in order to make possible the evaporation of the ethylene glycol. The compartment of the freeze dryer including the sample was brought from atmospheric pressure down to 10⁻³ mbar approximately in 3 hours approximately. The temperature was 25° C. approximately throughout the operation. After bringing back to atmospheric pressure, the deposit of silver oxalate deposited on the glass slide did not form a continuous layer due to the small amount of silver oxalate deposited from the solution.

The glass slide comprising the deposit resulting from the oxalate solution was subsequently placed in a laser lithography device as described in Example 1. Laser irradiation was carried out while adjusting the focus of a laser with a wavelength of 405 nm at the glass slide/deposit of silver oxalate interface. The diameter of the laser beam was 2 μm approximately, the rate of displacement of the sample under the laser beam was 1 mm·s⁻¹ approximately and the power density of the laser was 0.9×10⁶ W/cm² approximately.

The pattern to be irradiated was a line with a length of 5 mm and was preprogrammed on the lithography device.

A line of silver metal with a maximum width of 10 μm was obtained.

However, the small amount of material deposited due to the use of an oxalate solution in place of an oxalate suspension did not make it possible to form a continuous line of silver after laser irradiation.

1. Process for the manufacture of a metal, ceramic or metal-ceramic composite part or of a supported metal, ceramic or metal-ceramic composite microstructure, wherein said process comprises at least the following stages:
i) the deposition of a suspension or of a powder of at least one metal oxalate, optionally as a mixture with one or more compounds resulting from the partial decomposition of said metal oxalate, on at least a portion of a surface of a solid substrate, in order to form a layer of said metal oxalate optionally as a mixture with said compound or compounds,
it being understood that:
the metal oxalate corresponds to the following formula (I):
M₂(C₂O₄)ᵥ.nH₂O (I)
in which:
M is a metal cation in the +v oxidation state or a mixture of metal cations with a +v mean oxidation state,
v is an integer such that 1≤v≤4,
n is such that n≥0, and
the metal oxalate of the suspension or of the powder is in the form of particles and/or of agglomerates of particles, with a mean size ranging from 10 nm to 100 μm,
ii) the local heating of at least one zone of the layer of stage i), using a laser beam operating at a wavelength ranging from 150 nm to 2000 nm, at a power density sufficient to irreversibly transform the layer of the locally heated zone into a metal, ceramic or metal-ceramic composite layer exhibiting a pattern corresponding to the heated zone,
iii) optionally removing the non-heated zones of the layer, and
iv) optionally the repetition, one or more times, of the sequence of stages i) to ii) or i) to iii), so as to form one or more new metal, ceramic or metal-ceramic composite layer(s) on at least a portion of a free surface of the solid substrate and/or on at least a portion of the preceding metal, ceramic or metal-ceramic composite layer.

2. Process according to claim 1, wherein the metal cation M of the metal oxalate of formula (I) is chosen from Ag⁺, Li⁺, Cu²⁺, Fe²⁺, Ni²⁺, Mn²⁺, Co²⁺, Zn²⁺, Mg²⁺, Sr²⁺, Ba²⁺, Sn²⁺, Ca²⁺, Cd²⁺, Fe³⁺, Cr³⁺, Bi³⁺, Ce³⁺, Al³⁺, Sb³⁺, Ga³⁺, In³⁺, Y³⁺, La³⁺, Am³⁺, Zr⁴⁺, Hf⁴⁺ and U⁴⁺.

3. Process according to claim 1, wherein the solid substrate is made of glass, of metal, of glass-ceramic, of ceramic, of plastic or of any material which is resistant and/or inert with regard to the heating of stage ii) brought about by the laser beam.

4. Process according to claim 1, wherein the layer formed in stage i) exhibits a thickness ranging from 1 to 700 μm.

5. Process according to claim, wherein said metal oxalate of formula (I), and optionally the compound or compounds originating from the partial decomposition of said metal oxalate of formula (I).

6. Process according to claim 1, wherein said metal oxalate of formula (I), represent(s) at least 80% by weight, with respect to the total weight of the layer.

7. (canceled)

8. Process according to claim 1, wherein the suspension is a suspension of a metal oxalate of formula (I), optionally as a mixture with one or more compounds resulting from the partial decomposition of said metal oxalate of formula (I), in a solvent chosen from polyols, simple alcohols, tetrahydrofuran, dodecane, water and a mixture of at least two of the abovementioned solvents, if they are miscible.

9. Process according to claim 1, wherein stage i) is carried out by depositing the suspension of the metal oxalate of formula (I), optionally as a mixture with one or more compounds originating from the partial decomposition of said metal oxalate of formula (I), on at least a portion of a surface of the solid substrate and by then drying said suspension.

10. Process according to claim 1, wherein stage i) is carried out by directly depositing the powder of the metal oxalate of formula (I), optionally as a mixture with one or more compounds originating from the partial decomposition of said metal oxalate of formula (I), on at least a portion of a surface of the solid substrate.

11. Process according to claim 1, wherein stage ii) is carried out at a power density ranging from 0.1×10⁶ to 10×10⁶ W/cm².

12. Process according to claim 1, wherein stage ii) is carried out with a laser beam exhibiting a diameter ranging from 1 to 70 μm.

13. Process according to claim 1, wherein stage ii) is carried out several times before or after stage iii).

14. (canceled)

15. Process according to claim 1, wherein the metal, ceramic or metal-ceramic composite layer formed in stage ii) and the metal, ceramic or metal-ceramic composite layers formed in stage iv), if stage iv) exists, are not separated from the solid substrate and form a supported microstructure.

16. Process according to claim 15, wherein the solid substrate is a transparent substrate and the metal cation of the oxalate of formula (I) used in stage i) is a cation of a conductive metal.

17. Process according to claim 1, wherein said process comprises stage iv) and the metal, ceramic or metal-ceramic composite layers formed in stages ii) and iv) form a part which is separated from the solid substrate according to a stage v).

18-21. (canceled)
